(19) United States
(12) Patent Application Publication
(10) Pub. No.: US 2024/0096965 A1
(43) Pub. Date: Mar. 21, 2024

(54) SEMICONDUCTOR DEVICE

(71) Applicant: FUJI ELECTRIC CO., LTD., Kanagawa (JP)

(72) Inventors: Kaname MITSUZUKA, Matsumoto-city (JP); Yuki KARAMOTO, Matsumoto-city (JP)

(21) Appl. No.: 18/518,566

(22) Filed: Nov. 23, 2023

Related U.S. Application Data
(63) Continuation of application No. PCT/JP2022/039640, filed on Oct. 25, 2022.

(30) Foreign Application Priority Data
Dec. 27, 2021 (JP) 2021-212016

(51) Int. Cl. H01L 29/10; H01L 29/06; H01L 29/40; H01L 29/423; H01L 29/739

(52) U.S. Cl. CPC H01L 29/1095; H01L 29/0696; H01L 29/404; H01L 29/407; H01L 29/4236; H01L 29/7397

(57) ABSTRACT

Provided is a semiconductor device comprising a gate trench portion and a first trench portion adjacent to the gate trench portion, the semiconductor device comprising: a drift region of a first conductivity type; a base region of a second conductivity type; an emitter region of the first conductivity type that is provided above the base region and has a higher doping concentration than that of the drift region; and a contact region of the second conductivity type that is provided above the base region and has a higher doping concentration than that of the base region. In a mesa portion between the gate trench portion and the first trench portion, the contact region may have a first contact portion and a second contact portion that are provided to extend from the first trench portion to below a lower end of the emitter region.

The contents of the following patent application(s) are incorporated herein by reference:
NO. 2021-212016 filed in JP on Dec. 27, 2021
NO. PCT/JP2022/039640 filed in WO on Oct. 25, 2022

### BACKGROUND

### 1. Technical Field

The present invention relates to a semiconductor device.

### 2. Related Art

Patent Document 1 describes “improving characteristics such as saturation current in semiconductor devices”.

### PRIOR ART DOCUMENT

### Patent document

Patent Document 1: Japanese Patent Application Publication No. 2018-195798
Patent Document 2: WO2018/052098

A semiconductor device with improved latch-up withstand capability during switching is provided.

### BRIEF DESCRIPTION OF THE DRAWINGS

FIG. 1A shows an example of a top view of a semiconductor device 100.

FIG. 1B illustrates an example of an a-a′ cross-sectional view in FIG. 1A.

FIG. 1C illustrates an example of a b-b′ cross-sectional view in FIG. 1A.

FIG. 1D shows an example of an enlarged diagram of a front surface 21 of the semiconductor device 100.

FIG. 1E shows an example of an enlarged diagram of a lower end of an emitter region 12.

FIG. 1F shows an example of a c-c′ cross-sectional view in FIG. 1D.

FIG. 1G shows an example of a d-d′ cross-sectional view in FIG. 1D.

FIG. 2 is a diagram for describing an example of a manufacturing method of the semiconductor device 100.

FIG. 3 shows an example of a top view of the semiconductor device 100 including an unopened portion of a contact hole 54.

FIG. 4A shows an example of a top view of the semiconductor device 100.

FIG. 4B illustrates an example of an e-e′ cross-sectional view in FIG. 4A.

FIG. 5A shows an example of a top view of the semiconductor device 100 in a modification example.

FIG. 5B illustrates an example of an f-f′ cross-sectional view in FIG. 5A.

FIG. 6A shows an example of a top view of the semiconductor device 100 in a modification example.

FIG. 6B illustrates an example of a g-g′ cross-sectional view in FIG. 6A.

FIG. 7A shows an example of a top view of the semiconductor device 100 in a modification example.

FIG. 7B illustrates an example of an h-h′ cross-sectional view in FIG. 7A.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

In the present specification, one side in a direction parallel to a depth direction of a semiconductor substrate is referred to as an “upper” side, and the other side is referred to as a “lower” side. One surface of two principal surfaces of a substrate, a layer, or other member is referred to as a front surface, and the other surface is referred to as a back surface. “Upper”, “lower”, “front”, and “back” directions are not limited to a direction of gravity, or a direction of an attachment to a substrate or the like when a semiconductor device is mounted.

In the present specification, technical matters may be described using orthogonal coordinate axes of an X axis, a Y axis, and a Z axis. In the present specification, the XY plane is the plane parallel to the front surface of the semiconductor substrate, and the Z axis is the direction that forms a right-handed system with the X axis and Y axis and is parallel to the depth direction of the semiconductor substrate.

Each example embodiment shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each example embodiment respectively have opposite polarities.

In the present specification, a character N or P specifying a layer or a region means that electrons or holes are majority carriers, respectively. Also, ‘+’ and ‘−’ attached on ‘N’ and ‘P’ respectively mean that the higher doping concentration and the lower doping concentration than the layer or region to which these symbols are not attached.

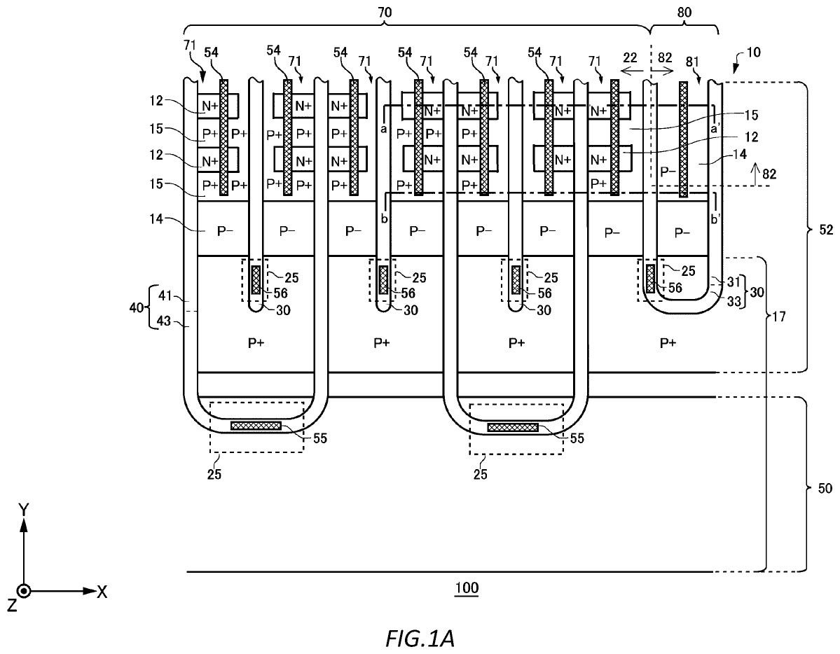

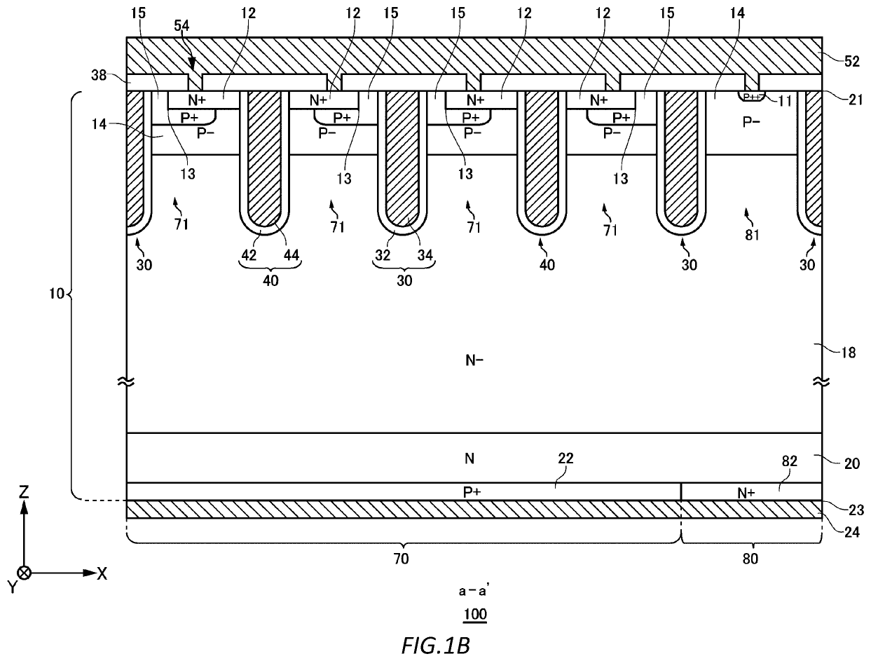

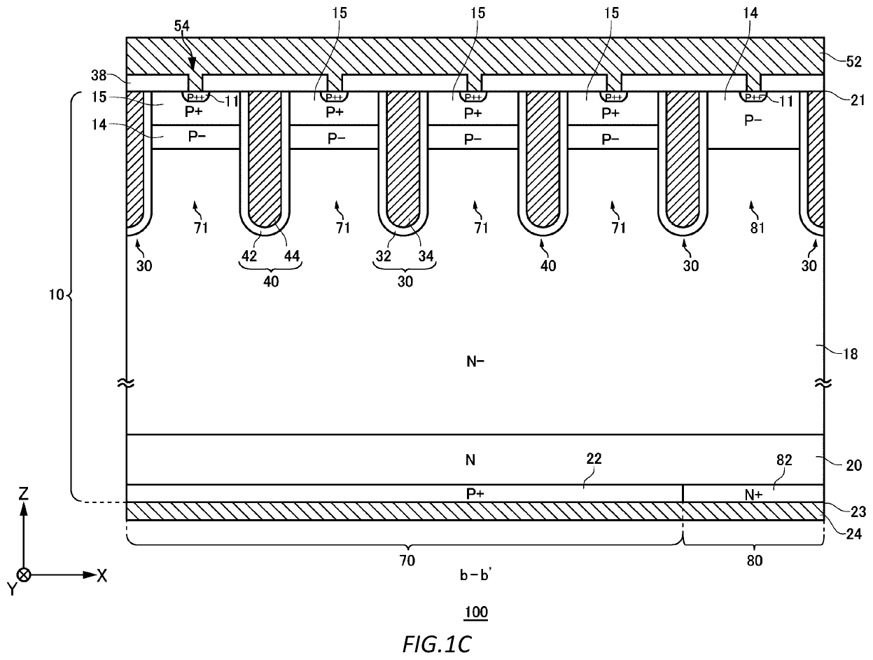

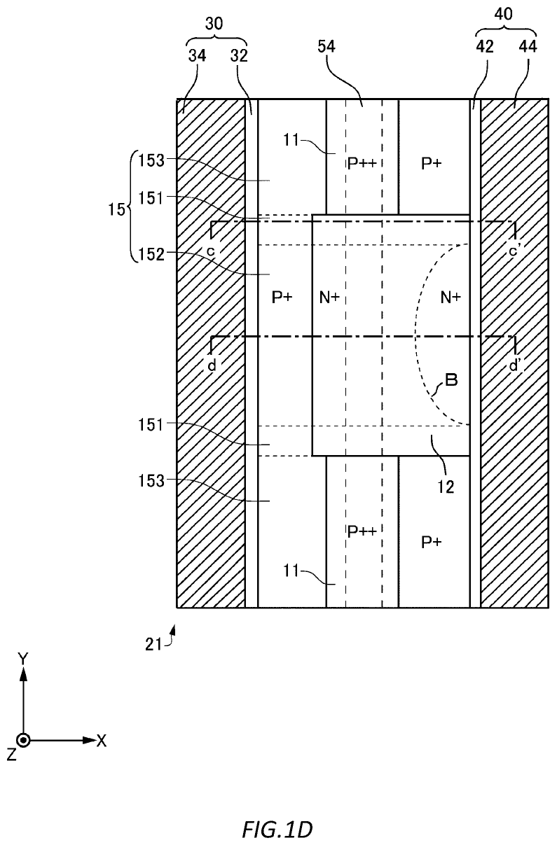

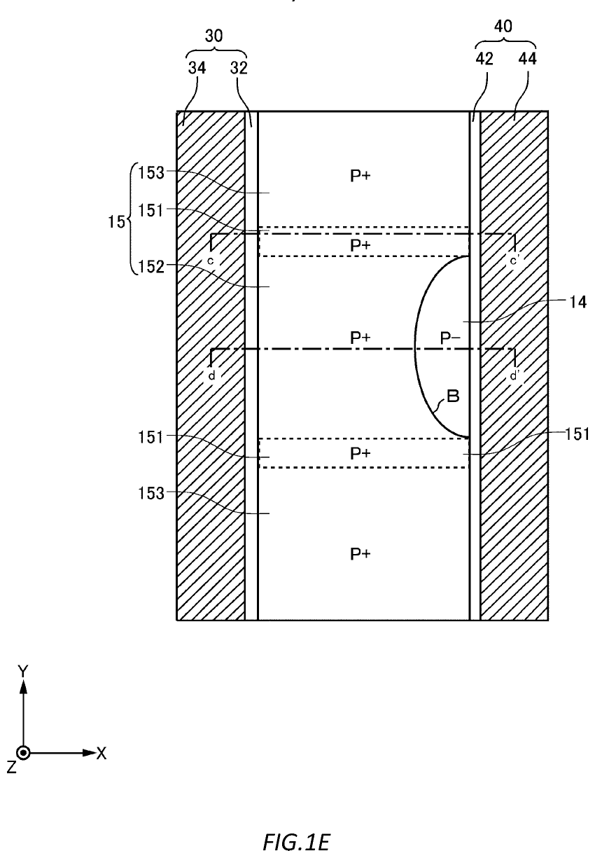

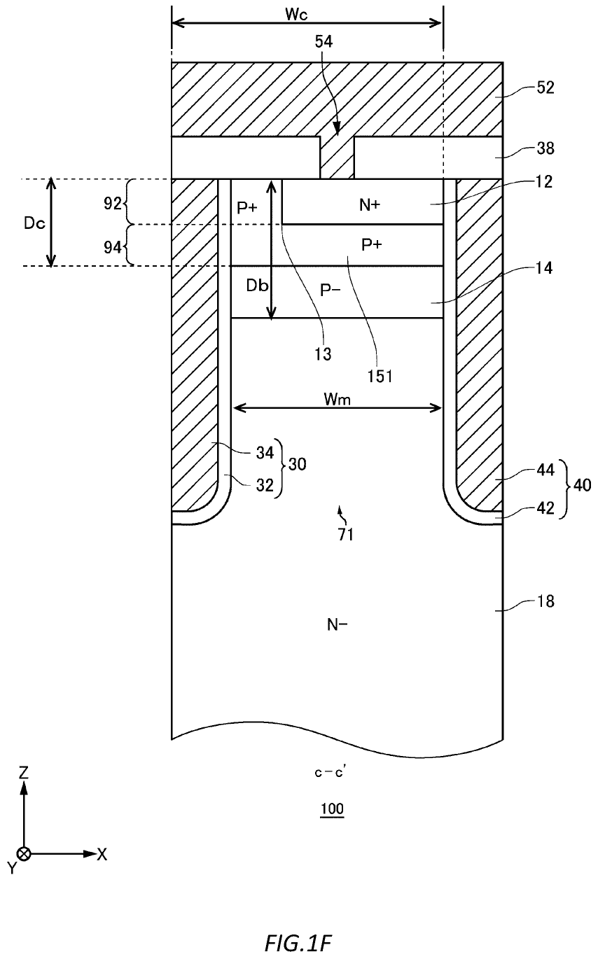

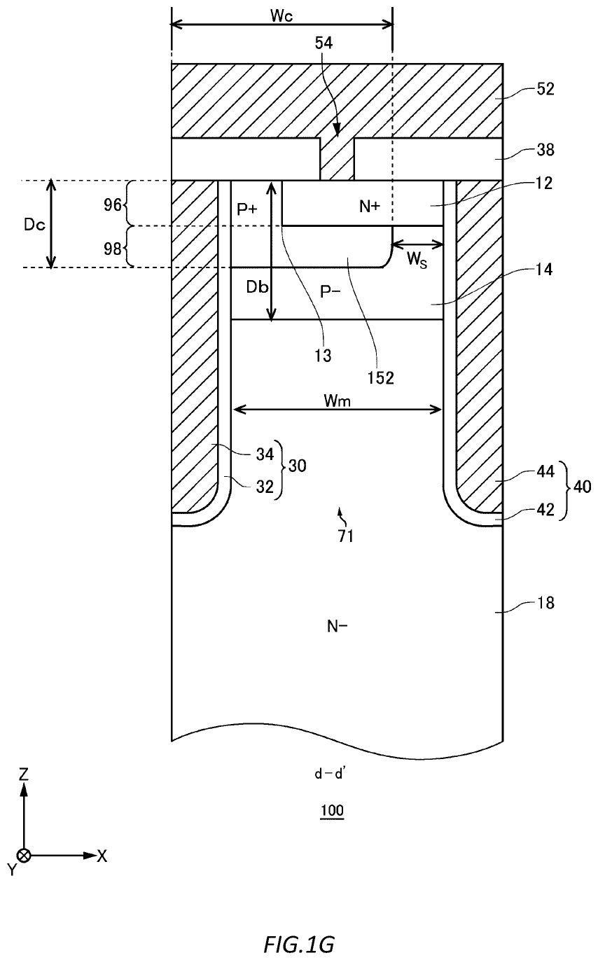

FIG. 1A shows an example of the top view of a semiconductor device 100. The semiconductor device 100 of the present example is a semiconductor chip including a transistor portion 70 and a diode portion 80. For example, the semiconductor device 100 is a trench gate type RC-IGBT (Reverse Conducting Insulated Gate Bipolar Transistor) in which a plurality of trench portions are arrayed. In the present example, the plurality of trench portions are in a striped pattern in which the trench portions are arrayed in the X axis direction and extend in the Y axis direction.

The transistor portion 70 is the region with the collector region 22 provided on the back surface side of the semiconductor substrate 10 being projected onto the upper surface of the semiconductor substrate 10, as described below in FIG. 1B. The collector region 22 has the second conductivity type. The collector region 22 in the present example is of the P+ type as an example. The transistor portion 70 includes transistors such as IGBTs.

The diode portion 80 is the region with the cathode region 82 provided on the back surface side of the semiconductor substrate 10 being projected onto the upper surface of the semiconductor substrate 10, as described below in FIG. 1B. The cathode region 82 has the first conductivity type. The cathode region 82 in the present example is of the N+ type as an example. The diode portion 80 includes a diode such as a free wheel diode (FWD) provided being adjacent to the transistor portion 70 at the upper surface of the semiconductor substrate 10.

FIG. 1A illustrates a surrounding region of a chip end portion, which is an edge side of the semiconductor device 100, and the other regions are omitted. For example, an edge termination structure portion is provided in the region on the negative side of the Y axis direction in the semiconductor device 100 in the present example. The edge termination structure portion is to reduce an electric field strength in the upper surface side of the semiconductor substrate 10. The edge termination structure portion includes, for example, a guard ring, a field plate, or a RESURF structure, or combinations thereof. Note that although the present example describes the edge in the negative side in the Y axis direction for convenience, the same applies to other edges of the semiconductor device 100.

The semiconductor substrate 10 may be a silicon substrate, may be a silicon carbide substrate, or may be a nitride semiconductor substrate such as gallium nitride, or the like. The semiconductor substrate 10 in the present example is a silicon substrate.

The semiconductor device 100 of the present example includes a gate trench portion 40, a dummy trench portion 30, an emitter region 12, a base region 14, a contact region 15, and a well region 17, on the front surface of the semiconductor substrate 10. Also, the semiconductor device 100 of the present example includes an emitter electrode 52 and a gate metal layer 50, which are provided above the front surface of the semiconductor substrate 10.

The emitter electrode 52 is provided above the gate trench portion 40, the dummy trench portion 30, the emitter region 12, the base region 14, the contact region 15, and the well region 17. In addition, the gate metal layer 50 is provided above the gate trench portion 40 and the well region 17.

The emitter electrode 52 and the gate metal layer 50 are formed of a material including metal. For example, at least a partial region of the emitter electrode 52 is formed of aluminum, aluminum-silicon alloy or aluminum-silicon-copper alloy. At least a partial region of the gate metal layer 50 may be formed of aluminum, aluminum-silicon alloy, or aluminum-silicon-copper alloy. The emitter electrode 52 and the gate metal layer 50 may include a barrier metal formed of titanium, titanium compound, or the like, which underlies a region formed of aluminum or the like. The emitter electrode 52 and the gate metal layer 50 are provided separately from each other.

The emitter electrode 52 and the gate metal layer 50 are provided above the semiconductor substrate 10 to sandwich an interlayer dielectric film 38. The interlayer dielectric film 38 is omitted in FIG. 1A. The interlayer dielectric film 38 is provided with contact holes 54, contact holes 55, and contact holes 56 penetrating therethrough.

The contact holes 55 are connected to the gate metal layer 50 and the gate conductive portion inside the gate trench portion 40 of the transistor portion 70. Inside the contact hole 55, a plug formed of tungsten or the like may be formed.

The contact hole 56 connects the emitter electrode 52 with a dummy conductive portion in a dummy trench portion 30. Inside the contact hole 56, a plug formed of tungsten or the like may be formed.

The connecting portion 25 electrically connects a front surface side electrode such as the emitter electrode 52 or the gate metal layer 50 to the semiconductor substrate 10. In an example, the connecting portion 25 is provided between the gate metal layer 50 and the gate conductive portion. The connecting portion 25 is also provided between the emitter electrode 52 and the dummy conductive portion. The connecting portion 25 is formed of a conductive material such as polysilicon doped with impurities. Here, the connecting portion 25 is formed of polysilicon (N+) doped with the impurities of the N type. The connecting portion 25 is provided above the front surface of the semiconductor substrate 10 via a dielectric film such as an oxide film, or the like.

The gate trench portions 40 are arrayed in a predetermined interval along a predetermined trench array direction (the X axis direction in the present example). As one example, the gate trench portions 40 are arrayed at a trench interval of 1.5 μm from adjacent trench portions, but the trench interval is not limited to this interval. The gate trench portion 40 in the present example may have two extending portions 41 extending along the trench extending direction perpendicular to the trench array direction and parallel to the front surface of the semiconductor substrate 10 (Y axis direction in the present example), and a connection portion 43 for connecting the two extending portions 41.

At least a part of the connection portion 43 is preferably formed in a curved shape. When the end portions of the two extending portions 41 of the gate trench portion 40 are connected to each other, the electric field strength at the end portions of the extending portions 41 can be reduced. At the connection portion 43 of the gate trench portion 40, the gate metal layer 50 may be connected to the gate conductive portion.

The dummy trench portion 30 in the present example is connected electrically to the emitter electrode 52, and is a trench portion set at the emitter potential. The dummy trench portions 30 are, similar to the gate trench portions 40, arrayed in a predetermined interval along a predetermined trench array direction (the X axis direction in the present example). As one example, the dummy trench portions 30 are arrayed at a trench interval of 1.5 μm from adjacent trench portions, but the trench interval is not limited to this interval. In particular, the trench interval of the dummy trench portions 30 may be provided to be different from the trench interval of the gate trench portions 40. The dummy trench portion 30 of the present example may have, similarly to the gate trench portion 40, a U shape at the front surface of the semiconductor substrate 10. That is, the dummy trench portion 30 may have two extending portions 31 extending along the trench extending direction, and connection portions 33 to connect the two extending portions 31. The dummy trench portion 30 may be set at a floating potential where it is not set at a predetermined potential. The dummy trench portion 30 is an example of the first trench portion adjacent to the gate trench portion 40.

As described above, the first trench portion adjacent to the gate trench portion 40 may be the dummy trench portion 30 set at an emitter potential. The first trench portion adjacent to the gate trench portion 40 may be the gate trench portion 40 set at a gate potential. Further, the first trench portion adjacent to the gate trench portion 40 may be a dummy gate trench portion 130 that is set at a gate potential and is not in contact with the emitter region 12. The dummy gate trench portion 130 will be described later.

The transistor portion 70 in the present example has a structure repeatedly arraying two gate trench portions 40 with the connection portion 43 and two dummy trench portions 30 without the connection portion. That is, the array ratio of the gate trench portion 40 to the dummy trench portion 30 may be set as a predetermined desired array ratio. In the transistor portion 70 in the present example, the ratio of the number of the gate trench portions 40 to the number of the dummy trench portions 30 is 1:1. The transistor portion 70 in the present example has a dummy trench portion 30 between the two extending portions 41 connected to the connection portion 43. Note that the number of the gate trench portions 40 may be the number of the extending portions 41. The number of the dummy trench portions 30 may be the number of the extending portions 31.

It is noted however that the ratio of the gate trench portions 40 and the dummy trench portions 30 is not limited to the present example. The ratio between the gate trench portions 40 and the dummy trench portions 30 may be 2:3 or may be 2:4. With respect to the gate trench portion 40, by increasing the number of the dummy trench portions 30, the electric field strength in the mesa portion 71 can be reduced, the withstand capability of the voltage and the current of the semiconductor device 100 can be increased. Also, by adjusting the ratio of the gate trench portion 40 to the dummy trench portion 30, the gate capacitance for driving the semiconductor device 100 can be adjusted. With respect to the gate trench portion 40, if the number of the dummy trench portion 30 is increased, the gate capacitance is increased, and the saturation current is reduced. Also, in the transistor portion 70, the dummy trench portion 30 is not provided, and the so-called full-gate structure, in which all the trench portions are gate trench portions 40, is also possible. Note that the ratio of the gate trench portion 40 to the dummy trench portion 30 disclosed in the present specification may be read as the ratio of gate trench portion 40 to dummy trench. The dummy trenches include trenches that do not have channels formed in the sidewalls, such as the dummy trench portion 30 or the dummy gate trench portion 130 described below.

The well region 17 is a region of a second conductivity type provided in the front surface side of the semiconductor substrate 10 than the drift region 18, which will be described below. The well region 17 is an example of the well region provided in the edge side of the semiconductor device 100. The well region 17 is of the P+ type as an example. The well region 17 is formed within a predetermined range from an end portion of the active region in a side in which the gate metal layer 50 is provided. A diffusion depth of the well region 17 may be deeper than depths of the gate trench portion 40 and the dummy trench portion 30. Partial regions, of the gate trench portion 40 and the dummy trench portion 30, in the gate metal layer 50 side are formed in the well region 17. The bottoms of the trench extending direction ends of the gate trench portions 40 and the dummy trench portions 30 may be covered by the well region 17.

The contact hole 54 is formed above each region of the emitter region 12 and the contact region 15 in the transistor portion 70. The emitter region 12 and contact region 15 are exposed in the contact hole 54. The contact hole 54 is not provided above the well regions 17 provided at both ends in the Y axis direction. In this manner, one or more contact holes 54 are formed in the interlayer dielectric film. One or more contact holes 54 may be provided to extend in the trench extending direction. Note that a plug region 11 (not shown) may be provided below the contact hole 54.

The plug region 11 may be provided below the contact hole 54. The plug region 11 may be provided in a region below the contact hole 54 and above the contact region 15. The plug region 11 may be provided in a region below the contact hole 54 and above the base region 14. The plug region 11 may be provided in the mesa portion 71, or may be provided in the mesa portion 81. The plug region 11 may not be provided in region below the contact hole 54 and above the emitter region 12. In this case, corresponding to the repeated structures of the emitter region 12 and the contact region 15, the plug region 11 may be discretely provided along the contact hole 54. Note that the plug region 11 may be provided in a region below the contact hole 54 and above the emitter region 12. The plug region 11 may be provided to extend in a Y axis direction along the contact hole 54 in the mesa portion 81.

The mesa portion 71 and the mesa portion 81 may be mesa portions provided adjacent to the trench portion in the surface parallel to the front surface of the semiconductor substrate 10. The mesa portion may be a portion of the semiconductor substrate 10 sandwiched by two trench portions that are adjacent to each other, and may be a portion from the front surface of the semiconductor substrate 10 down to the depth of the bottom portion, which is the deepest portion, of each trench portion. The extending portions of each trench portion may be regarded as one trench portion. That is, the region sandwiched between two extending portions may be set to be a mesa portion.

The mesa portion 71 is provided adjacent to at least one of the dummy trench portion 30 or the gate trench portion 40 in the transistor portion 70. The mesa portion 71 has the well region 17, the emitter region 12, the base region 14, and the contact region 15 on the front surface of the semiconductor substrate 10.

On the other hand, the mesa portion 81 is provided adjacent to the dummy trench portion 30 in the diode portion 80. The trench portion in the mesa portion 81 may be electrically connected to the emitter electrode 52 through the contact hole 56 and set at the emitter potential. That is, the trench portion provided in the diode portion 80 may be the dummy trench portion 30.

The mesa portion 81 has a well region 17 and a base region 14 on the front surface of the semiconductor substrate 10. Note that the emitter electrode 52 is arranged on the upper surface of the mesa portion 81. That is, the metal layer of the emitter electrode 52 may function as an anode electrode in the diode portion 80.

The base region 14 is the region of the second conductivity type provided in the front surface side of the semiconductor substrate 10 in the transistor portion 70. The base region 14 is of the P− type as an example. The base regions 14 may be provided at both end portions of the mesa portion 71 in the Y axis direction in the front surface 21 of the semiconductor substrate 10. Note that FIG. 1A illustrates only one end portion in the Y axis direction of the base region 14.

The emitter region 12 is a region of the first conductivity type which has a higher doping concentration than the drift region 18 described below in FIG. 1B. The emitter region 12 in the present example is of the N+ type as an example. For example, the dopant of the emitter region 12 is phosphorus (P) or arsenic (As) or the like. The emitter region 12 is provided in contact with the gate trench portion 40 at a front surface of the mesa portion 71. The emitter region 12 may be provided to extend in the X axis direction from one of two trench portions sandwiching the mesa portion 71 to the other of the two trench portions. The emitter region 12 is also provided below the contact hole 54. The emitter region 12 is connected to the emitter electrode 52 via the contact hole 54 provided while penetrating through the interlayer dielectric film 38.

The emitter region 12 may extend to the dummy trench portion 30 and be in contact with the dummy trench portion 30. Note that the emitter region 12 may terminate without reaching the dummy trench portion 30 and may not be in contact with the dummy trench portion 30. The emitter region 12 in the present example is not in contact with the dummy trench portion 30.

The contact region 15 is a region of the second conductivity type having a higher doping concentration than that of the base region 14. The contact region 15 in the present example is of the P+ type as an example. One example of the dopant of the contact region 15 is boron (B). The contact region 15 in the present example is provided in the front surface 21 of the mesa portion 71. The contact region 15 may be provided in the X axis direction from one of two trench portions sandwiching the mesa portion 71 to the other of the two trench portions. Note that the contact region 15 may be spaced apart from the gate trench portion 40 below the emitter region 12 in the portion where the emitter region 12 is in contact with the gate trench portion 40.

The contact region 15 may be or may not be in contact with the gate trench portion 40. In addition, the contact region 15 may be, or may not be in contact with the dummy trench portion 30. In the present example, the contact region 15 is in contact with the dummy trench portion 30 and the gate trench portion 40. The contact region 15 is also provided below the contact hole 54. Note that the contact region 15 may be provided in the mesa portion 81.

FIG. 1B illustrates an example of the a-a′ cross-sectional view in FIG. 1A. The cross section a-a′ is the XZ plane passing through the emitter region 12 in the transistor portion 70, from the transistor portion 70 to the diode portion 80. In the cross section a-a′, the semiconductor device 100 in the present example has the semiconductor substrate 10, the interlayer dielectric film 38, the emitter electrode 52, and a collector electrode 24. The emitter electrode 52 is formed above the semiconductor substrate 10 and the interlayer dielectric film 38.

The drift region 18 is a region of the first conductivity type which is provided in the semiconductor substrate 10. The drift region 18 in the present example is of the N− type as an example. The drift region 18 may be a region that has remained without other doping regions being formed in the semiconductor substrate 10. That is, the doping concentration of the drift region 18 may be a doping concentration of the semiconductor substrate 10.

A buffer region 20 is a region of the first conductivity type provided below the drift region 18. The buffer region 20 in the present example is of the N type as an example. The doping concentration of the buffer region 20 is higher than the doping concentration of the drift region 18. The buffer region 20 may function as a field stop layer which prevents a depletion layer spreading from the lower surface side of the base region 14 from reaching the collector region 22 of the second conductivity type and the cathode region 82 of the first conductivity type.

The collector region 22 is provided below the buffer region 20 in the transistor portion 70. The collector electrode 24 is formed on the back surface 23 of the semiconductor substrate 10. The collector electrode 24 is formed of a conductive material such as metal.

The base region 14 is a region of the second conductivity type provided above the drift region 18 in the mesa portion 71 and the mesa portion 81. The base region 14 is provided in contact with the gate trench portion 40. The base region 14 may be provided in contact with the dummy trench portion 30.

The emitter region 12 is provided between the base region 14 and the front surface 21 in the mesa portion 71. The emitter region 12 is provided in contact with the gate trench portion 40. The emitter region 12 may or may not be in contact with the dummy trench portion 30.

The plug region 11 is a region of the second conductivity type having a higher doping concentration than that of the contact region 15. The plug region 11 of the present example is of the P++ type, as an example. The plug region 11 in the present example is provided at the front surface 21. In the mesa portion 81, the plug region 11 is provided above the base region 14. The lower end of the plug region 11 may be provided to be shallower than the lower end of the emitter region 12. The plug region 11 may be provided to extend in a Y axis direction along the contact hole 54 in the mesa portion 81.

One or more gate trench portions 40 and one or more dummy trench portions 30 are provided at the front surface 21. Each trench portion is provided from the front surface 21 to the drift region 18. In regions being provided with at least any of the emitter region 12, the base region 14 and the contact region 15, each trench portion penetrates these regions and reaches the drift region 18. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

The gate trench portion 40 has a gate trench, a gate dielectric film 42, and a gate conductive portion 44 which are formed in the front surface 21. The gate dielectric film 42 is formed to cover an inner wall of the gate trench. The gate dielectric film 42 may be formed by oxidizing or nitriding a semiconductor on the inner wall of the gate trench. The gate conductive portion 44 is formed on an inner side further than the gate dielectric film 42 in the gate trench. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 on the front surface 21. A potential of a gate electrode of an IGBT or the like is applied to the gate conductive portion 44.

The gate conductive portion 44 includes a region opposing the adjacent base region 14 in the mesa portion 71 side by sandwiching the gate dielectric film 42 in a depth direction of the semiconductor substrate 10. When a predetermined gate voltage is applied to the gate conductive portion 44, a channel as an inversion layer of electrons is formed in the interfacial surface layer of the base region 14 in contact with the gate trench.

The dummy trench portion 30 may have the same structure as the gate trench portion 40. The dummy trench portion 30 has a dummy trench, a dummy dielectric film 32, and a dummy conductive portion 34 which are formed in the front surface 21 side. The dummy dielectric film 32 is formed covering the inner walls of the dummy trench. The dummy conductive portion 34 is formed in the interior of the dummy trench and also formed inside the dummy dielectric film 32. The dummy dielectric film 32 insulates the dummy conductive portion 34 from the semiconductor substrate 10. The dummy trench portion 30 is covered by the interlayer dielectric film 38 in the front surface 21. A potential of an emitter electrode of an IGBT or the like is applied to the dummy conductive portion 34. The dummy conductive portion 34 may be a floating potential.

The interlayer dielectric film 38 is provided above the semiconductor substrate 10. The emitter electrode 52 is provided above the interlayer dielectric film 38. In the interlayer dielectric film 38, one or more contact holes 54 are provided for electrically connecting the emitter electrode 52 to the semiconductor substrate 10. Similarly, the contact hole 55 and the contact hole 56 may be provided to penetrate through the interlayer dielectric film 38.

The lower-end end portion 13 is a lower end of the emitter region 12 in the mesa portion 71, and is the lower end on the dummy trench portion 30 side. When the emitter region 12 reaches the dummy trench portion 30, the lower-end end portion 13 comes into contact with the dummy trench portion 30.

At least a part of the contact region 15 is provided below the lower-end end portion 13 in the mesa portion 71. That is, the contact region 15 is provided to be deeper than the emitter region 12, and provided to be overlapped with a part of the emitter region 12. The contact region 15 in the present example is provided to extend from the dummy trench portion 30 to below the lower-end end portion 13 of the emitter region 12 in the trench array direction. Accordingly, it becomes difficult for holes below the emitter region 12 to be extracted directly through the emitter region 12. This makes it difficult for NPNP-type parasitic thyristors from the emitter region 12 to the collector region 22 to turn on, thereby able to suppress latch-up of the semiconductor device 100.

In the cross section of the present example, the contact region 15 is spaced apart from the gate trench portion 40 at the mesa portion 71. In this way, the contact region 15 does not prevent the inversion layer from being formed on the side surface of the gate trench portion 40 to allow the stable operation of the semiconductor device 100.

The contact region 15 in the present example is provided to span both sides of the dummy trench portion 30 in the X axis direction. In the manufacturing process of the contact region 15 in the present example, the semiconductor substrate 10 is provided with a mask and the contact region 15 across the region provided with the trench portion can be ion-implanted. The dummy trench portion 30 may be provided by etching the semiconductor substrate 10 after providing the contact region 15.

For miniaturization or the like of the semiconductor device 100, miniaturization of a so-called process pitch is performed to reduce the interval between the mesa portions 71. For example, when diffusion regions are provided by ion implantation in a silicon semiconductor substrate 10, dopants tend to diffuse within a certain range. By the structure of the contact region 15 in the present example, even if the process pitch is miniaturized, the contact region 15, which extends to below the lower-end end portion 13 of the emitter region 12 and which is spaced apart from the gate trench portion 40, is easy to manufacture. This can provide semiconductor devices 100 with high latch-up withstand capability without significantly affecting electrical characteristics. Note that the contact region 15 can achieve an effect of suppressing the latch-up as long as it is provided to be connected to the lower end of the emitter region 12 in the trench extending direction, but it is not limited to a form of the contact region 15 in contact with the dummy trench portion 30.

In the diode portion 80, the buffer region 20 is stacked above the cathode region 82, and the drift region 18 is stacked above the buffer region 20. In the mesa portion 81, the base region 14 is stacked above the drift region 18, and a PN junction is formed between the base region 14 and the drift region 18. The base region 14 is connected electrically to the emitter electrode 52 via the contact holes 54.

FIG. 1C illustrates an example of the b-b′ cross-sectional view in FIG. 1A. The cross section b-b′ is an XZ plane passing through contact regions 15 in the transistor portion 70 without passing the emitter regions 12. In the present example, the mesa portion 71 in the transistor portion 70 has a base region 14, a contact region 15, and a plug region 11 above the drift region 18. By providing the plug region 11, RBSOA (Reverse Bias Safe Operation Area) withstand capability is improved. In the diode portion 80, the mesa portion 81 may have a structure similar to that of the example shown in FIG. 1B.

The contact region 15 extends from the gate trench portion 40 to the dummy trench portion 30. The contact holes 54 are provided above the contact region 15. The hole is extracted from the contact region 15 and the plug region 11 via the contact hole 54. Lower ends of the contact region 15 may be positioned deeper than positions of lower ends of the plug region 11.

When the contact region 15 provided below the emitter region 12 and the contact region 15 in the cross section in the present example are provided by the same process, the depth of the contact regions 15 are provided to be the same depth. In this case, the contact region 15 is deeper than the emitter region 12. Note that the contact region 15 may be provided with different depths in other regions below the emitter region 12.

FIG. 1D shows an example of an enlarged diagram of the front surface 21 of the semiconductor device 100. The c-c′ cross section shows an XZ plane passing through the first contact portion 151 described below. The d-d′ cross section shows an XZ plane passing through the second contact portion 152 described below. Dashes in the emitter region 12 indicate a boundary B between the second contact portion 152 and the base region 14 below the emitter region 12. The contact region 15 of the present example has a first contact portion 151, a second contact portion 152, and a third contact portion 153.

The first contact portion 151 and the second contact portion 152 are provided to extend from the first trench portion to below the lower end of the emitter region 12 in the mesa portion 71. Although the first trench portion of the present example is the dummy trench portion 30, it may be the gate trench portion 40 or the dummy gate trench portion 130. Similarly in other example embodiments, even when the first trench portion is described as the dummy trench portion 30, it may be changed as appropriate to the gate trench portion 40 or the dummy gate trench portion 130.

As shown in the top view of FIG. 1D, the first contact portion 151 and the second contact portion 152 are provided to have a step at the end portion at the gate trench portion 40 side. In the present example, the step between the first contact portion 151 and the second contact portion 152 is formed to have an arc shape as the boundary B, but the shape of the boundary B is not limited thereto.

The first contact portion 151 is provided to extend further from the dummy trench portion 30 than the second contact portion 152 in the trench array direction. The first contact portion 151 is positioned closer to the end portion side of the emitter region 12 than the second contact portion 152 in the trench extending direction. The first contact portion 151 of the present example is in contact with the gate trench portion 40 in the trench array direction, but may be spaced apart from the gate trench portion 40. The first contact portion 151 may be provided on the front surface 21 of the semiconductor substrate 10 at the sidewall of the dummy trench portion 30.

The second contact portion 152 is positioned closer to the center portion side of the emitter region 12 than the first contact portion 151 in the trench extending direction. The center portion of the emitter region 12 in the trench extending direction corresponds to the d-d′ cross section position. The second contact portion 152 may be provided on the front surface 21 of the semiconductor substrate 10 at the sidewall of the dummy trench portion 30.

The third contact portion 153 is provided in a region in which the emitter region 12 is not formed in a top view. The third contact portion 153 may be provided to extend from the dummy trench portion 30 to the gate trench portion 40 at the front surface 21. The third contact portion 153 of the present example is alternately provided with the emitter region 12 along the trench extending direction at the front surface 21.

The first contact portion 151, the second contact portion 152, and the third contact portion 153 each may have the same doping concentration. That is, the first contact portion 151, the second contact portion 152, and the third contact portion 153 may be simultaneously formed by the same ion implantation process.

FIG. 1E shows an example of an enlarged diagram at the lower end of the emitter region 12. The present figure corresponds to an XY plane at a deeper position than the XY plane shown in FIG. 1D.

Below the emitter region 12, the first contact portion 151 is in contact with the gate trench portion 40. The first contact portion 151 is in contact with the base region 14, the second contact portion 152, and the third contact portion 153.

Below the emitter region 12, the second contact portion 152 is spaced apart from the gate trench portion 40. Below the emitter region 12, the second contact portion 152 is positioned at a position closer to a center portion side of the emitter region 12 than the first contact portion 151 in a trench extending direction. The second contact portion 152 of the present example is in contact with the base region 14 to form an arc shape at the boundary B in a top view.

The base region 14 is provided, below the emitter region 12, to be in contact with the second contact portion 152 and the third contact portion 153. In addition, in the center portion of the emitter region 12 in the trench extending direction, the lower end of the emitter region 12 is in contact with the base region 14.

FIG. 1F shows an example of a c-c′ cross-sectional view in FIG. 1D. The c-c′ cross section is the XZ plane that passes through the first contact portion 151 in the transistor portion 70.

The emitter region 12 extends beyond the contact hole 54 from the gate trench portion 40 to the dummy trench portion 30 side in the trench array direction. Accordingly, a current is easily caused to flow from the emitter region 12 through the contact hole 54. The emitter region 12 of the present example extends from the gate trench portion 40 to the dummy trench portion 30 side in the trench array direction, and is terminated before reaching the dummy trench portion 30. However, the emitter region 12 may be provided to extend from the gate trench portion 40 to the dummy trench portion 30 in the trench array direction.

The first contact portion 151 extends beyond the contact hole 54 from the dummy trench portion 30 which is the first trench portion in the trench array direction. The first contact portion 151 is provided on the front surface 21 of the semiconductor substrate 10, at the sidewall of the dummy trench portion 30. The first contact portion 151 includes an upper region 92 and a lower region 94.

The upper region 92 is a region having the same depth as the emitter region 12 in the semiconductor substrate 10. As one example, the depth of the upper region 92 is 0.5 μm. It is to be noted that the depth of the upper region 92 is not limited to this. When the emitter region 12 extends from the gate trench portion 40 to the dummy trench portion 30 and reaches the dummy trench portion 30, the upper region 92 is not provided in a cross section in which the emitter region 12 is exposed from the front surface 21 of the semiconductor substrate 10. For example, a doping concentration of the upper region 92 is 5E19/cm 3 or more and 2E20/cm³ or less. Note that E means exponentiations of 10, for example, 5E19/cm 3 means 5×10¹⁹/cm³.

The lower region 94 is provided in a region deeper than the emitter region 12 in the semiconductor substrate 10. The lower region 94 extends beyond the lower-end end portion 13 of the emitter region 12 from the dummy trench portion 30 to the gate trench portion 40 side. For example, a doping concentration of the lower region 94 is 1E19/cm³ or more and 1E20/cm³ or less.

The first contact portion 151 is in contact with the lower end of the emitter region 12. That is, an upper end of the lower region 94 is in contact with the lower end of the emitter region 12. The first contact portion 151 is also in contact with the lower-end end portion 13.

The width We is a width of the contact region 15 in the trench array direction. The width We is obtained by measuring the width from the center of the dummy trench portion 30 to the end portion of the gate trench portion 40 side of the contact region 15. That is, the width We corresponds to a maximum reachable position at the gate trench portion 40 side of the lower region 94, which is measured from the center of the dummy trench portion 30. The width We may be 1.2 μm or less, and may be 1.1 μm or less.

Herein, a width of the upper region 92 in the trench array direction may fall within a range of 15% or more and 40% or less of a mesa width Wm. The width of the lower region 94 in the trench array direction may be within a range of 30% or more and 70% or less of the mesa width Wm. A width in the trench array direction of a portion in which the lower region 94 is overlapped with the emitter region 12 may fall within a range of 0% or more and 30% or less, or even preferably, a range of 10% or more and 20% or less, of the mesa width Wm.

The thickness Dc is the thickness of the contact region 15 in the depth direction of the semiconductor substrate 10. The thickness Dc is thicker than a depth of the lower end of the emitter region 12, and less than a depth Db of the base region 14. For example, the thickness Dc is from 0.5 μm to 2.0 μm. The thickness of the upper region 92 may be within a range of 0.3 μm or more and 0.8 μm or less. The thickness of the lower region 94 may be in a range from 0.3 μm to 1.1 μm.

FIG. 1G shows an example of a d-d′ cross-sectional view in FIG. 1D. The d-d′ cross section is the XZ plane that passes through the second contact portion 152 in the transistor portion 70. In the present example, the difference between the d-d′ cross section and the c-c′ cross section of FIG. 1F is particularly described. Other points may be the same as those of the c-c′ cross section of FIG. 1F.

The second contact portion 152 extends beyond the contact hole 54 from the dummy trench portion 30 which is the first trench portion in the trench array direction. The second contact portion 152 is provided on the front surface 21 of the semiconductor substrate 10, at the sidewall of the dummy trench portion 30. The second contact portion 152 includes an upper region 96 and a lower region 98.

The upper region 96 is a region having the same depth as the emitter region 12 in the semiconductor substrate 10. As one example, the depth of the upper region 96 is 0.5 μm. It is to be noted that the depth of the upper region 96 is not limited to this. When the emitter region 12 extends from the gate trench portion 40 to the dummy trench portion 30 and reaches the dummy trench portion 30, the upper region 96 is not provided in a cross section in which the emitter region 12 is exposed from the front surface 21 of the semiconductor substrate 10. For example, a doping concentration of the upper region 96 is 5E19/cm 3 or more and 2E20/cm³ or less.

The lower region 98 is provided in a region deeper than the emitter region 12 in the semiconductor substrate 10. The lower region 98 extends beyond the lower-end end portion 13 of the emitter region 12 from the dummy trench portion 30 to the gate trench portion 40 side. The lower-end end portion 13 is an end portion on the dummy trench portion 30 side of the lower end of the emitter region 12. For example, a doping concentration of the lower region 98 is 1E19/cm 3 or more and 1E20/cm 3 or less.

The second contact portion 152 is in contact with the lower end of the emitter region 12. That is, an upper end of the lower region 98 is in contact with the lower end of the emitter region 12. The second contact portion 152 is also in contact with the lower-end end portion 13.

The width Ws is the distance between the contact region 15 and the gate trench portion 40 in the trench array direction. The width Ws may be provided to be capable to form the channel in the end portion of the gate trench portion 40. The width Ws of the present example shows a distance in which the second contact portion 152 and the gate trench portion 40 are spaced apart from each other in the trench array direction. In an example, the width Ws is 0.6 μm or more. The width Ws may be within a range of 10% or more and 50% or less of the mesa width Wm.

A magnitude of the step on the gate trench portion 40 side in the trench extending direction of the first contact portion 151 and the second contact portion 152 may be 10% or more and 50% or less of the mesa width Wm of the mesa portion 71. As the present example, when the first contact portion 151 is in contact with the gate trench portion 40, the magnitude of the step in the trench array direction of the first contact portion 151 and the second contact portion 152 is equal to the width Ws.

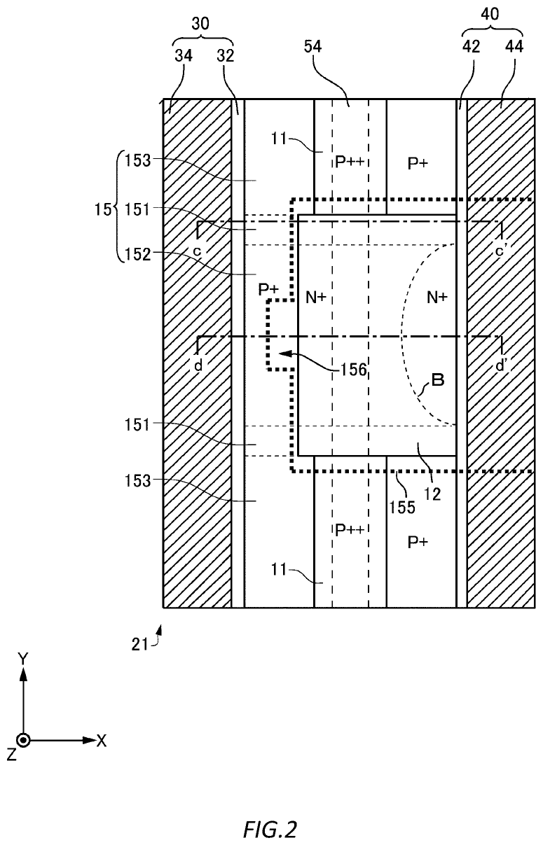

FIG. 2 is a diagram for describing an example of a manufacturing method of the semiconductor device 100. In the present figure, a mask 155 for forming the contact region 15 is indicated by dashes in the enlarged diagram of the front surface 21 of the semiconductor device 100 shown in FIG. 1D. The mask 155 includes a thinning region 156.

The thinning region 156 is a region in which a mask 155 is protruding outside at the center portion of the emitter region 12 in the trench extending direction. By providing the thinning region 156, when the dopant is diffused by annealing after the ion implantation, at the gate trench portion 40 side, the step of the first contact portion 151 and the second contact portion 152 can be formed.

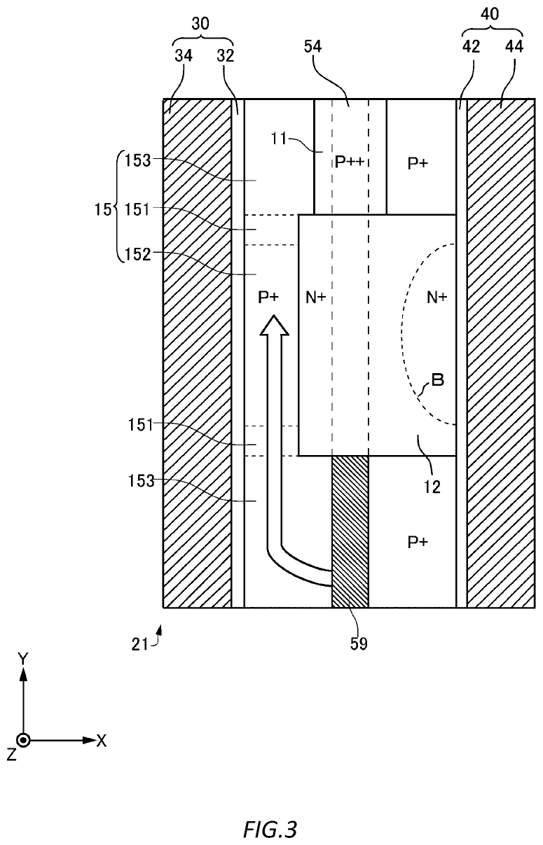

FIG. 3 shows an example of a top view of the semiconductor device 100 including an unopened portion of a contact hole 54.

The disconnected region 59 is a region in which the emitter electrode 52 is not electrically connected to the contact region 15 at the front surface 21 with the contact hole 54 not being opened. For example, the disconnected region 59 is an unopened region where the contact hole 54 is not formed in the interlayer dielectric film 38 due to oxide film etching defects or the like caused by particles or foreign matter or the like. Also, the disconnected region 59 may be a region where the contact region 15 of the front surface 21 is not formed due to resist remaining or the like.

In the present example, the hole current that would have been extracted in the disconnected region 59 flows through the contact region 15 and is extracted via the contact hole 54 above the other neighboring contact region 15. That is, the hole current does not flow through the base region 14 below the emitter region 12, but through the contact region 15, which has lower resistance to holes than the base region 14, thus can suppress latch-up. This suppresses switching breakdowns caused by process defects. Therefore, a semiconductor device 100 including an element structure that is strong to process defects and has redundancy can be provided.

In addition, since the semiconductor device 100 of the present example can extract the hole via the first contact portion 151 and the second contact portion 152 provided below the emitter region 12, the latch-up can be further easily suppressed. The semiconductor device 100 of the present example may cause the emitter region 12 to extend to the dummy trench portion 30 which is a first trench portion, since semiconductor device 100 of the present example includes the first contact portion 151 and the second contact portion 152 below the emitter region 12.

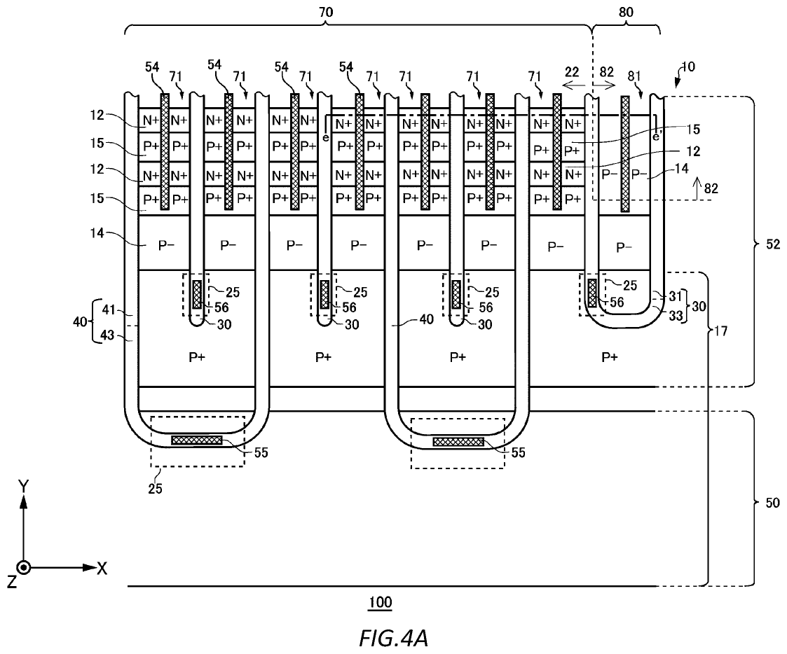

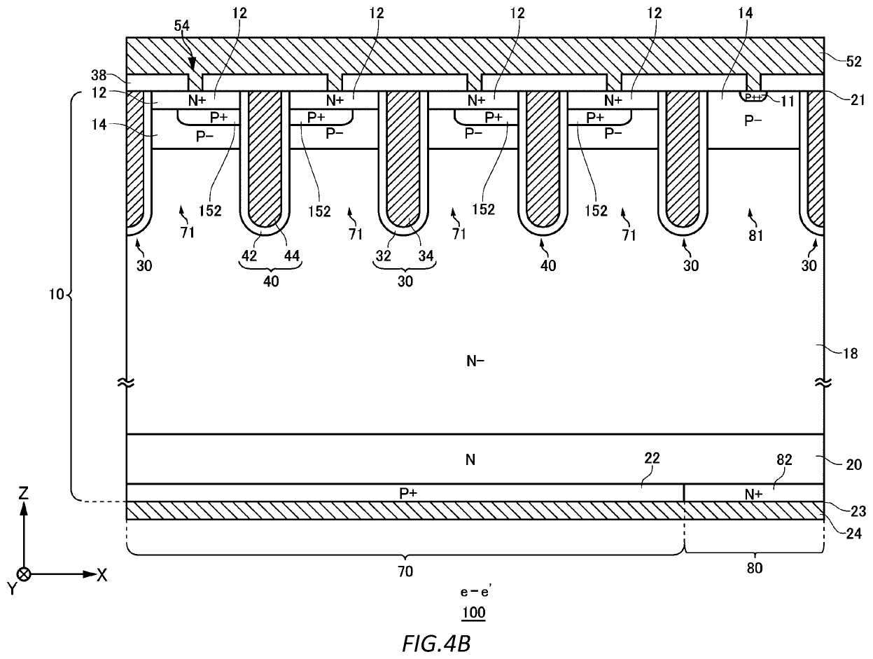

FIG. 4A shows an example of the top view of a semiconductor device 100. In the present example, the emitter region 12 is different from FIG. 1A in a point of being provided to be in contact with the dummy trench portion 30. In this example, difference with FIG. 1A will be particularly described.

The emitter region 12 in the present example extends from the gate trench portion 40 to the dummy trench portion 30 in the trench array direction. The emitter region 12 and the contact region 15 are provided to be in contact with each of the gate trench portion 40 and the dummy trench portion 30 alternately with respect to the trench extending direction in the front surface 21 of the semiconductor substrate 10.

The plug region 11 may be provided in a region which is sandwiched between the contact regions 15 of the mesa portion 71 in the trench array direction. The plug region 11 may not be provided in a region which is sandwiched between the emitter regions 12 of the mesa portion 71 in the trench array direction. Note that the plug region 11 may be provided in a region which is sandwiched by the emitter regions 12 of the mesa portion 71 in the trench array direction. The plug region 11 may be provided to extend in the trench extending direction in the mesa portion 81.

FIG. 4B illustrates an example of an e-e′ cross-sectional view in FIG. 4A. The cross section e-e′ is the XZ plane passing through the emitter region 12 in the transistor portion 70, from the transistor portion 70 to the diode portion 80. Note that the XZ cross section passing through the second contact portion 152 in the transistor portion 70 from the transistor portion 70 to the diode portion 80 is the same as that of the FIG. 1C.

The second contact portion 152 of the present example is provided below the emitter region 12 in the mesa portion 71. Similarly, in another cross section, the first contact portion 151 is provided below the emitter region 12. In this way, the hole below the emitter region 12 can be extracted through the first contact portion 151 and the second contact portion 152, to suppress the latch-up.

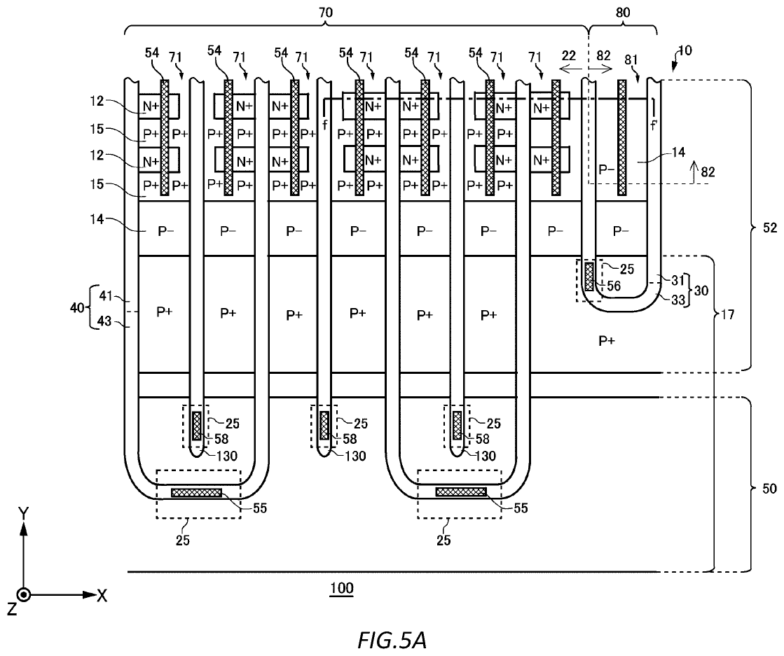

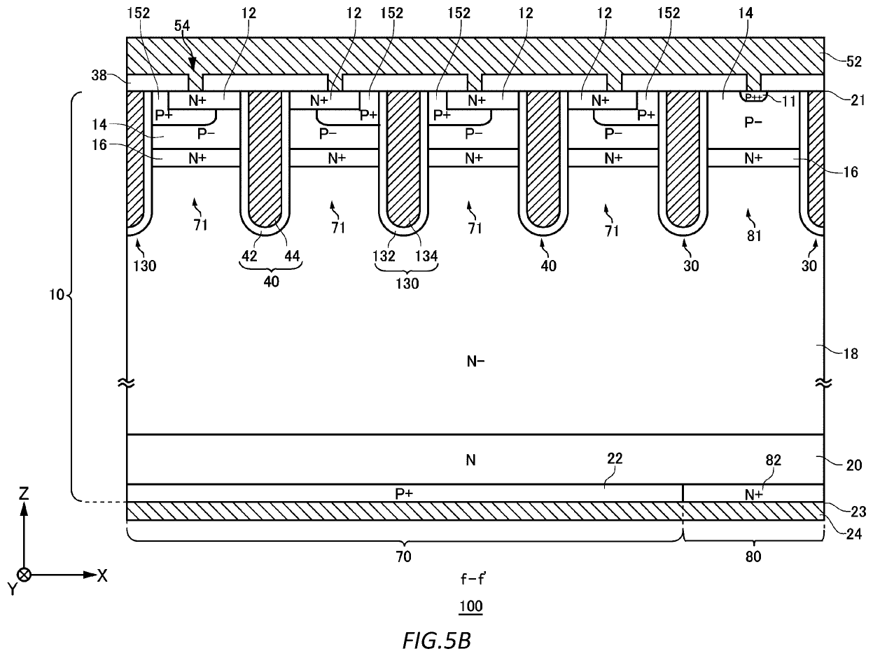

FIG. 5A shows an example of the top view of the semiconductor device 100 in the modification example. In this example, difference with FIG. 1A will be particularly described. The semiconductor device 100 of the present example includes, as the first trench portion, the dummy gate trench portion 130 that is not in contact with the emitter region 12.

The dummy gate trench portion 130 is a trench portion not in contact with the emitter region 12 and set at the gate potential. That is, the dummy gate trench portion 130 is set to a gate potential, but does not form a channel near the sidewall. In order to set the dummy gate trench portion 130 at the gate potential, the dummy gate trench portion 130 extends, in the Y axis direction, to the region in which the gate metal layer 50 is provided. The dummy gate trench portion 130 is set at the gate potential, connected to the gate metal layer 50 via the contact holes 58.

Although the dummy gate trench portion 130 is set at the gate potential, since it is not in contact with the emitter region 12, the channel is not formed by the inversion layer of the first conductivity type on the sidewall of the dummy gate trench portion 130. The dummy gate trench portion 130 has a different nature of the gate capacitance or the like from those of the dummy trench portion 30 since dummy gate trench portion 130 causes the carrier to be easily withdrawn to the mesa portion 71. Accordingly, by using the dummy gate trench portion 130 and the dummy trench portion 30 in combination, the threshold voltage in the semiconductor device 100, the saturation current, the electric field strength, the gate capacitance or the like can be adjusted.

On the front surface 21 of the semiconductor substrate 10, the gate trench portion 40 in the present example has a U-shaped structure, while the dummy gate trench portion 130 has an I-shaped structure. However, the structures of gate trench portion 40 and dummy gate trench portion 130 are not limited to these structures as long as the desired array ratio can be achieved.

In the present example, the structure of the dummy trench portion 30 in the diode portion 80 is similar to the structure shown in FIG. 1A. That is, the dummy trench portion 30 is connected to the emitter electrode 52 via the contact hole 56 and is set at the emitter potential.

FIG. 5B illustrates an example of an f-f′ cross-sectional view in FIG. 5A. The cross section f-f′ is the XZ plane passing through the emitter region 12 in the transistor portion 70, from the transistor portion 70 to the diode portion 80. The dummy gate trench portion 130 has a second gate dielectric film 132 and a second gate conductive portion 134. The semiconductor device 100 of the present example has an accumulation region 16 between the drift region 18 and the base region 14.

The accumulation region 16 is a region of the first conductivity type provided between the base region 14 and the drift region 18. The accumulation region 16 in the present example is of the N+ type as an example. The accumulation region 16 is provided in the transistor portion 70 and the diode portion 80. This allows the semiconductor device 100 to avoid mask misalignment in the accumulation region 16. The accumulation region 16 is provided in contact with gate trench portions 40. The accumulation region 16 may be or may not be in contact with the dummy trench portion 30.

The doping concentration of the accumulation region 16 is higher than the doping concentration of the drift region 18. The dose amount of ion implantation to the accumulation region 16 may be 1E12 cm⁻² or more and 1E13 cm⁻² or less. In addition, the dose amount of ion implantation to the accumulation region 16 may also be 3E12 cm⁻² or more and 6E12 cm⁻² or less. By providing the accumulation region 16, the carrier injection enhancement effect (Injection Enhancement effect) can be improved, and the ON voltage of the transistor portion 70 can be decreased.

In the present example, the semiconductor device 100 is different from the semiconductor device 100 of FIG. 1B in that the semiconductor device 100 in the present example has the dummy gate trench portion 130 being set to an emitter potential. Note that, also in the present example, the contact region 15 is electrically connected to the lower end of the emitter region 12 below the emitter region 12. Accordingly, the semiconductor device 100 can suppress the latch-up by using the structure of the contact region 15 regardless of the potential of the dummy gate trench portion 130.

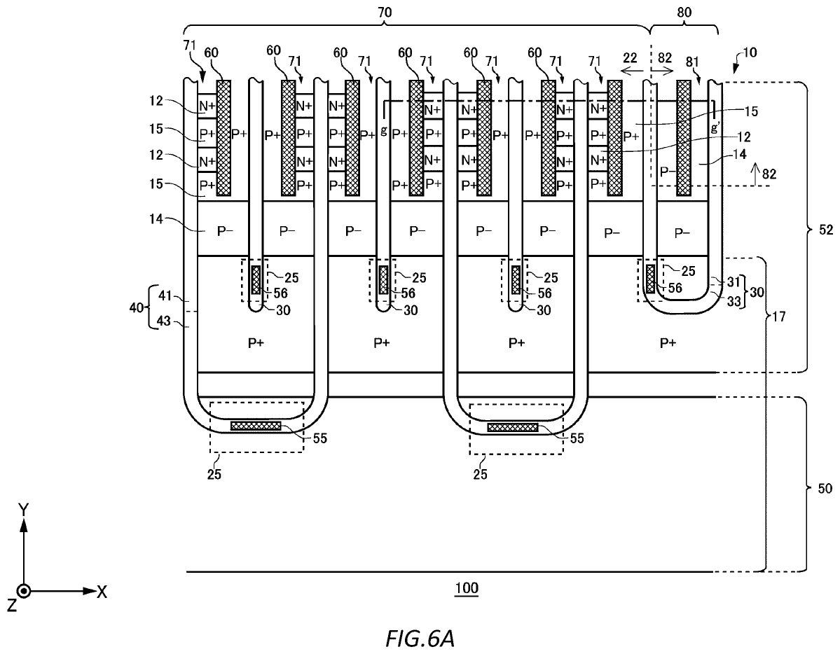

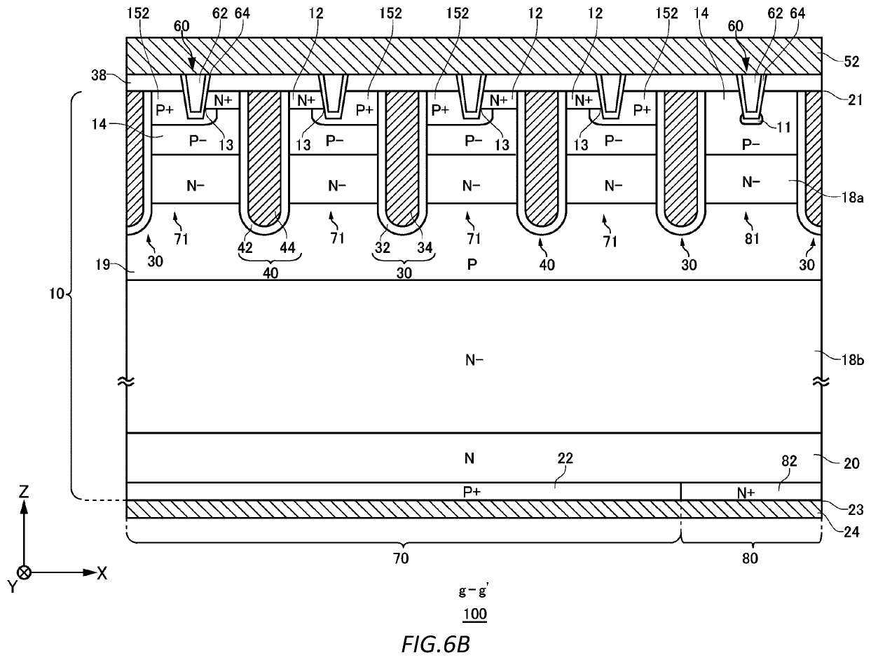

FIG. 6A shows an example of the top view of the semiconductor device 100 in the modification example. The semiconductor device 100 in the present example includes a contact trench portion 60.

The contact trench portion 60 is provided to extend in the depth direction of the semiconductor substrate 10 from the front surface 21. The contact trench portion 60 electrically connects the emitter electrode 52 and the semiconductor substrate 10. The contact trench portion 60 is provided to extend in the trench extending direction. The contact trench portion 60 in the present example is arranged in a striped shape along the gate trench portion 40 and the dummy trench portion 30.

The contact trench portion 60 is formed above each region of the emitter region 12 and the contact region 15 in the transistor portion 70. The contact trench portion 60 is formed above the region of the base region 14 in the diode portion 80. The contact trench portion 60 is not provided above the well regions 17, which are provided on both ends in the Y axis direction. One or more contact trench portions 60 may be provided to extend in the trench extending direction.

The emitter region 12 is provided to be in contact with the gate trench portion 40. The emitter region 12 is provided to extend from the gate trench portion 40 to the sidewall of the contact trench portion 60 in the trench array direction. The emitter region 12 may be not provided between the dummy trench portion 30 and the contact trench portion 60.

The contact region 15 of the emitter region 12 may be alternately arranged in the trench extending direction between the gate trench portion 40 and the contact trench portion 60. In the trench extending direction, the width of the contact region 15 may be greater than the width of the emitter region 12. The width of the emitter region 12 in the trench extending direction may be from 0.6 μm to 1.6 μm. By controlling the ratio of the emitter region 12 to the contact region 15 appropriately, the latch-up can be easily suppressed.

The plug region 11 may be provided in a region adjacent to the contact region 15 of the mesa portion 71 in the trench array direction. The plug region 11 may not be provided in a region adjacent to the emitter region 12 of the mesa portion 71 in the trench array direction. Note that the plug region 11 may be provided in a region adjacent to the emitter region 12 of the mesa portion 71 in the trench array direction. The plug region 11 may be provided to extend in the trench extending direction along the contact trench portion 60 in the mesa portion 81.

FIG. 6B is an example of a g-g′ cross-sectional view in FIG. 6A. The contact trench portion 60 of the present example is formed to be deeper than the emitter region 12.

The contact trench portion 60 is provided to extend to the back surface 23 side of the semiconductor substrate 10 further than the front surface 21. The contact trench portion 60 of the present example is provided to extend to the back surface 23 side of the semiconductor substrate 10 further than the emitter region 12. That is, the lower end of the contact trench portion 60 in the present example is deeper than the lower end of the emitter region 12. The lower end of the contact trench portion 60 of the present example is shallower than the lower end of the second contact portion 152. The contact trench portion 60 of the present example has a plug 62 and a barrier metal layer 64.

The plug 62 is made of a conductive material provided inside the contact trench portion 60. The plug 62 may be made of the same material as the emitter electrode 52, or may be a different material. The plug 62 may include a material such as tungsten.

The barrier metal layer 64 is provided below the plug 62. The barrier metal layer 64 in the present example is provided between the plug 62 and the emitter region 12. The barrier metal layer 64 may include a material such as titanium nitride.

The emitter region 12 is provided to be in contact with the gate trench portion 40. The emitter region 12 may or may not be in contact with the dummy trench portion 30. The emitter region 12 is provided to extend from the gate trench portion 40 to the sidewall of the contact trench portion 60 in the trench array direction. Therefore, the lower-end end portion 13 is positioned on the sidewall of the contact trench portion 60, between the gate trench portion 40 and the contact trench portion 60 in the trench array direction.

At least a part of the second contact portion 152 is provided below the lower-end end portion 13 in the mesa portion 71. The second contact portion 152 of the present example is provided to extend from the dummy trench portion 30 to below the lower-end end portion 13 of the emitter region 12 in the trench array direction. The second contact portion 152 may extend beyond the contact trench portion 60 from the dummy trench portion 30 in the trench array direction, or does not need to extend beyond the contact trench portion 60.

The trench bottom region 19 is a second conductivity type region provided below the dummy trench portion 30 and the gate trench portion 40. The trench bottom region 19 in the present example covers the lower ends of the dummy trench portion 30 and the gate trench portion 40. The doping concentration of the trench bottom region 19 may be less than the base region 14. The trench bottom region 19 is provided between the drift region 18a and the drift region 18b. By providing the trench bottom region 19, the avalanche capability can be improved. Note that the embodiment where the semiconductor device 100 includes the trench bottom region 19 may be described, but the trench bottom region 19 may also be omitted.

The drift region 18a is provided between the base region 14 and the trench bottom region 19 in the mesa portion 71 and the mesa portion 81. The drift region 18b is provided below the trench bottom region 19. The doping concentration of the drift region 18a and the drift region 18b may be the same.

The plug region 11 may be provided to be in contact with the lower end of the contact trench portion 60. The plug region 11 may be provided at the sidewall of the contact trench portion 60. The plug region 11 of the present example covers the lower end of the contact trench portion 60 and a part of the sidewall of the contact trench portion 60. The lower end of the plug region 11 may be provided to be shallower than the lower end of the base region 14. The plug region 11 may be formed by implanting ions to the lower end of a groove which is for forming the contact trench portion 60.

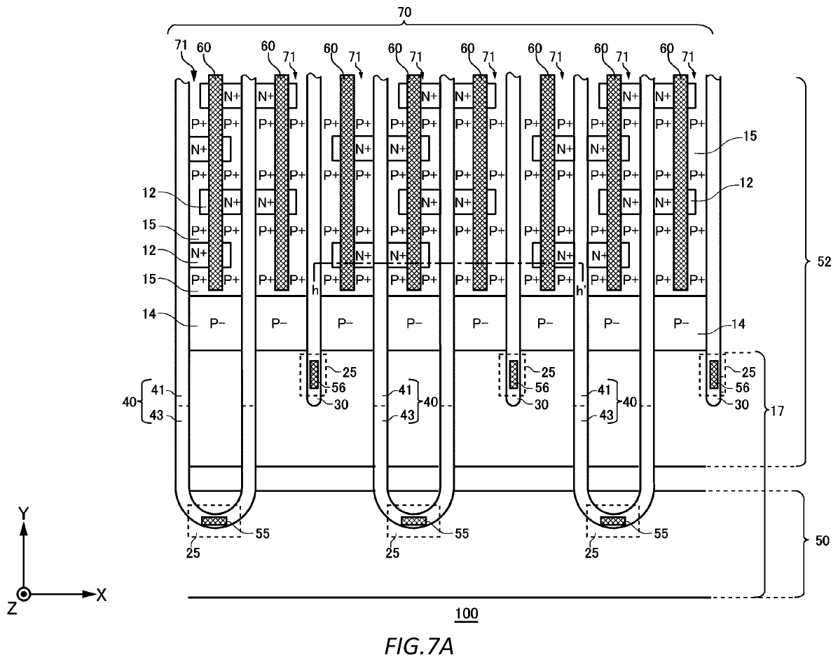

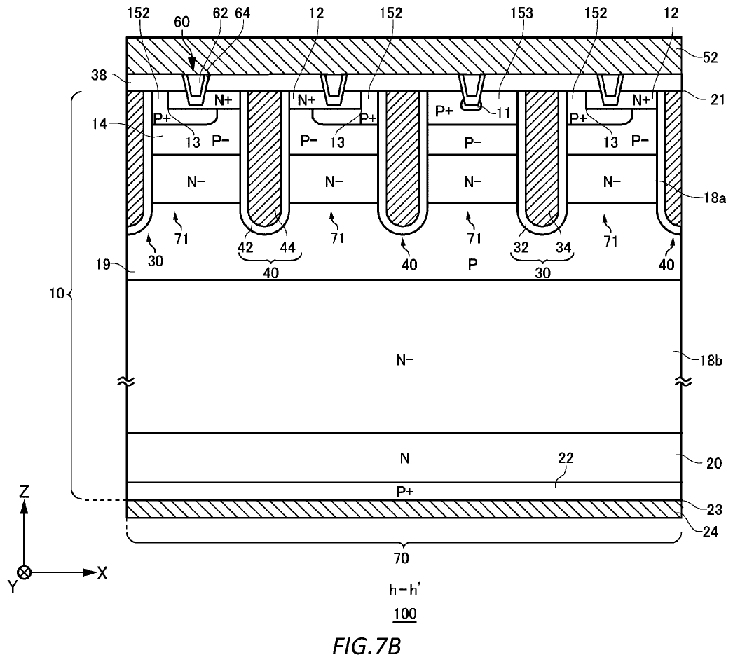

FIG. 7A shows an example of the top view of the semiconductor device 100 in the modification example. The semiconductor device 100 of the present example is of a case where the first trench portion adjacent to the gate trench portion 40 is the gate trench portion 40, and includes a staggered structure. Although the semiconductor device 100 of the present example does not include the diode portion 80, it may include the diode portion 80. The semiconductor device 100 has a plurality of gate trench portions 40 provided to be adjacent. The plurality of gate trench portions 40 provided to be adjacent may be connected to each other by the connection portion 43.

The plurality of gate trench portions 40 provided to be adjacent are in different locations in the trench extending direction and contact with the emitter region 12. That is, the semiconductor device 100 includes emitter regions 12, with the staggered structure, arrayed alternately. In this case, each of the adjacent gate trench portions 40 has both of the portion that becomes a gate trench portion and the portion that becomes the first trench portion. That is, in the mesa portion between the adjacent gate trench portions 40, an emitter region 12 (first emitter region) being in contact with one gate trench portion 40 and spaced apart from the other gate trench portion 40, and an emitter region 12 (second emitter region) being spaced apart from one gate trench portion 40 and in contact with the other gate trench portion 40 are included.

The contact region 15 is provided in a region including a portion below the lower-end end portion 13 of the other gate trench portion 40 side of the first emitter region and a portion below the lower-end end portion 13 of one gate trench portion 40 side of the second emitter region. Also, in the trench extending direction of the gate trench portion 40, the first emitter region and the second emitter region are provided alternately sandwiching the contact region 15.

FIG. 7B illustrates an example of an h-h′ cross-sectional view in FIG. 7A. The semiconductor device 100 in the present example includes a contact trench portion 60 shallower than the emitter regions 12 and the emitter regions 12 provided on both ends of the contact trench portion 60 in the trench array direction, but it is not limited to this. That is, the semiconductor device 100 may include a contact trench portion 60 deeper than the emitter region 12, and may also include an emitter region 12 provided on one side of the contact trench portion 60. The semiconductor device 100 may include a trench bottom region 19 or may not.

The plug region 11 may be provided in a region adjacent to the contact region 15. The plug region 11 may be provided between the contact trench portion 60 and the contact region 15. The plug region 11 may be sandwiched between the contact regions 15 in the trench array direction. The plug region 11 of the present example is not provided in a region adjacent to the emitter region 12. Note that the plug region 11 may be provided in a region adjacent to the emitter region 12. In this case, the plug region 11 may penetrate or may not penetrate the emitter region 12. When the plug region 11 does not penetrate the emitter region 12, the plug region 11 may be in contact with the contact region 15 in another XZ cross section.

While the present invention has been described by way of the embodiments, the technical scope of the present invention is not limited to the above-described embodiments. It is apparent to persons skilled in the art that various alterations or improvements can be made to the above-described embodiments. It is also apparent from the description of the claims that embodiments added with such alterations or improvements can be included in the technical scope of the present invention.

The operations, procedures, steps, and stages of each process performed by an apparatus, system, program, and method illustrated in the claims, embodiments, or diagrams can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

### EXPLANATION OF REFERENCES

10 semiconductor substrate
11 plug region
12 emitter region
13 lower-end end portion
14 base region
15 contact region
16 accumulation region
17 well region
18 drift region
19 trench bottom region
20 buffer region
21 front surface
22 collector region
23 back surface
24 collector electrode
25 connecting portion
30 dummy trench portion
31 extending portion
32 dummy dielectric film
33 connection portion
34 dummy conductive portion
38 interlayer dielectric film
40 gate trench portion
41 extending portion
42 gate dielectric film
43 connection portion
44 gate conductive portion
50 gate metal layer
52 emitter electrode
54 contact hole
55 contact hole
56 contact hole
58 contact hole
59 disconnected region
60 contact trench portion
62 plug
64 barrier metal layer
70 transistor portion
71 mesa portion
80 diode portion
81 mesa portion
82 cathode region
92 upper region
94 lower region
96 upper region
98 lower region
100 semiconductor device
130 dummy gate trench portion
132 second gate dielectric film
134 second gate conductive portion
151 first contact portion
152 second contact portion
153 third contact portion
155 mask
156 thinning region

What is claimed is:

1. A semiconductor device comprising a gate trench portion and a first trench portion adjacent to the gate trench portion, the semiconductor device comprising:
a drift region of a first conductivity type provided in a semiconductor substrate;
a base region of a second conductivity type provided above the drift region;
an emitter region of the first conductivity type that is provided above the base region and has a higher doping concentration than that of the drift region; and
a contact region of the second conductivity type that is provided above the base region and has a higher doping concentration than that of the base region, wherein
in a mesa portion between the gate trench portion and the first trench portion, the contact region has a first contact portion and a second contact portion that are provided to extend from the first trench portion to below a lower end of the emitter region; and
the first contact portion is provided to extend from a position that is closer to the first trench portion than the second contact portion in a trench array direction.

2. The semiconductor device according to claim 1, wherein
below the emitter region, the second contact portion is positioned at a position closer to a center portion side of the emitter region than the first contact portion in a trench extending direction.

3. The semiconductor device according to claim 1, wherein
the first contact portion and the second contact portion are in contact with the lower end of the emitter region.

4. The semiconductor device according to claim 2, wherein
the first contact portion and the second contact portion are in contact with the lower end of the emitter region.

5. The semiconductor device according to claim 1, wherein
in a center portion of the emitter region in a trench extending direction, the lower end of the emitter region is in contact with the base region.

6. The semiconductor device according to claim 1, wherein
below the emitter region, the first contact portion is in contact with the gate trench portion; and
below the emitter region, the second contact portion is spaced apart from the gate trench portion.

7. The semiconductor device according to claim 6, wherein
the second contact portion is spaced apart by 0.6 μm or more from the gate trench portion in the trench array direction.

8. The semiconductor device according to claim 1, wherein
a magnitude of a step in the trench array direction of the first contact portion and the second contact portion is 10% or more and 50% or less of a mesa width of the mesa portion.

9. The semiconductor device according to claim 1, wherein the first contact portion and the second contact portion are provided on a front surface of the semiconductor substrate at a sidewall of the first trench portion.

10. The semiconductor device according to claim 1, further comprising an interlayer dielectric film provided above the semiconductor substrate,
wherein the emitter region is connected to an emitter electrode via a contact hole provided penetrating through the interlayer dielectric film.

11. The semiconductor device according to claim 10, wherein
the emitter region extends beyond the contact hole from the gate trench portion in the trench array direction.

12. The semiconductor device according to claim 11, wherein
the emitter region extends from the gate trench portion and terminates without reaching the first trench portion in the trench array direction.

13. The semiconductor device according to claim 11, wherein
the second contact portion extends beyond the contact hole from the first trench portion in the trench array direction.

14. The semiconductor device according to claim 1, wherein
the contact region has a third contact portion that is alternately provided with the emitter region along a trench extending direction in a front surface of the semiconductor substrate.

15. The semiconductor device according to claim 1, wherein
the first trench portion is a dummy trench portion set at an emitter potential.

16. The semiconductor device according to claim 1, wherein
the first trench portion includes a dummy gate trench portion set at a gate potential and being not in contact with the emitter region.

17. The semiconductor device according to claim 1, wherein
the first trench portion is a gate trench portion set at a gate potential.

18. The semiconductor device according to claim 17, wherein
the emitter region has, in the mesa portion, a first emitter region that is in contact with the gate trench portion and spaced apart from the first trench portion; and
the contact region is provided, in the mesa portion, below a lower end of the first trench portion side of the first emitter region.

19. The semiconductor device according to claim 18, wherein
the emitter region includes, in the mesa portion, a second emitter region that is in contact with the first trench portion and is spaced apart from the gate trench portion, and
the contact region is also provided, in the mesa portion, below a lower end of the second emitter region on the gate trench portion side.

20. The semiconductor device according to claim 19,
wherein the first emitter region and the second emitter region are alternately provided in a trench extending direction of the gate trench portion.
